(19) United States
(12) Patent Application Publication
(10) Pub. No.: US 2002/0175297 A1
(43) Pub. Date: Nov. 28, 2002

(54) Methods and apparatus for ion implantation with variable spatial frequency scan lines

(76) Inventors: Jay T. Scheuer, Rowley, MA (US); Gregory R. Gibilaro, Topsfield, MA (US)

Correspondence Address: Gary L. Loser, Esq., Varian Semiconductor Equipment, Associates, Inc., 35 Dory Road, Gloucester, MA, 01930, US

(21) Appl. No.: 10/152,887

(22) Filed: May 21, 2002

Related U.S. Application Data
(60) Provisional application No. 60/293,754, filed on May 25, 2001.

(51) Int. Cl. H01J 37/302

(52) U.S. Cl. 250/492.21

(57) ABSTRACT

Methods and apparatus for controlled ion implantation of a workpiece, such as a semiconductor wafer, are provided. The method includes generating an ion beam, scanning the ion beam across the workpiece in a first direction to produce scan lines, translating the workpiece in a second direction relative to the ion beam so that the scan lines are distributed over the workpiece with a standard spatial frequency, acquiring a dose map of the workpiece, and initiating a dose correction implant and controlling the spatial frequency of the scan lines during the dose correction, if the acquired dose map is not within specification and a required dose correction is less than a minimum dose correction that can be obtained with the standard spatial frequency of the scan lines.

### CROSS REFERENCE TO RELATED APPLICATION

This application claims the benefit of provisional application Serial No. 60/293,754, filed May 25, 2001, which is hereby incorporated by reference in its entirety.

### FIELD OF THE INVENTION

This invention relates to systems and methods for ion implantation of semiconductor wafers and other workpieces and, more particularly, to systems and methods for ion implantation wherein scan lines with variable spatial frequency are utilized to control dose accuracy and dose uniformity.

### BACKGROUND OF THE INVENTION

Ion implantation is a standard technique for introducing conductivity-altering impurities into semiconductor wafers. A desired impurity material is ionized in an ion source, the ions are accelerated to form an ion beam of prescribed energy, and the ion beam is directed at the surface of the wafer. The energetic ions in the beam penetrate into the bulk of the semiconductor material and are embedded into the crystalline lattice of the semiconductor material to form a region of desired conductivity.

Ion implantation systems usually include an ion source for converting a gas or a solid material into a well-defined ion beam. The ion beam is mass analyzed to eliminate undesired ion species, is accelerated to a desired energy and is directed onto a target plane. Most ion implanters use an ion beam that is much smaller than the wafer in both dimensions and distribute the dose from the ion beam across the wafer by scanning the beam electronically, by moving the wafer mechanically or by a combination of beam scanning and wafer movement. Ion implanters which utilize a combination of electronic beam scanning and mechanical wafer movement are disclosed in U.S. Pat. No. 4,922,106 issued May 1, 1990 to Berrian et al. and U.S. Pat. No. 4,980,562 issued Dec. 25, 1990 to Berrian et al. These patents describe techniques for scanning and dosimetry control in such systems.

Important goals of the scanning and dose control systems in an ion implanter are dose accuracy and dose uniformity. That is, the ion implanter is required to implant a specified dose of dopant atoms in the wafer and to achieve a specified dose uniformity across the surface of the wafer. In order to achieve dose uniformity and dose accuracy, prior art ion implanters have utilized a variable electronic scan speed and a nearly constant mechanical translation speed, resulting in scan lines that are uniformly spaced over the surface of the wafer. A complete implant of a wafer may involve several complete passes over the wafer until the desired total dose is achieved. The spacing between scan lines is typically less than the beam height in the mechanical translation direction to ensure overlap of scan lines and to achieve dose uniformity.

As noted, a typical implant protocol may involve multiple complete passes over the wafer. The beam is electronically scanned over a Faraday cup which measures the beam current at intervals during the implant. The dose measurements are used to generate a dose map of the implanted wafer. Because the dose map is based on measured beam current, variations in beam current are taken into account. The dose map is evaluated by the dose control system by comparing it with a specified dose map. In areas where the actual dose is less than the specified dose, dose correction scanning is performed.

However, under certain conditions, dose correction may not be possible utilizing prior art dose control algorithms. In particular, the scanning system may be characterized by a minimum dose correction that can be applied to the wafer. The minimum correction arises from the fact that the ion beam current is substantially fixed during a given implant, and the electronic scanning speed has a maximum value based on the characteristics of the scan amplifier. Thus, the dose correction that can be applied to the wafer has a lower limit. If the required dose correction is less than the minimum correction, the desired dose cannot be achieved with prior art scanning techniques. If the minimum correction is applied to the wafer in this case, the actual dose exceeds the desired dose. If the minimum correction is not applied to the wafer, the actual dose remains less than the desired dose.

Accordingly, there is a need for improved ion implantation methods and apparatus.

### SUMMARY OF THE INVENTION

The present invention is described in connection with ion implanters wherein the ion beam is scanned electronically in one direction, typically horizontally, and the wafer or other workpiece is translated mechanically in a second direction, typically vertically, to distribute the ion beam over the wafer surface. The electronic scanning of the ion beam produces scan lines, and the mechanical translation of the wafer distributes the scan lines over the wafer surface. The spatial frequency of the scan lines on the wafer is controlled to control dose and dose uniformity.

According to a first aspect of the invention, a method is provided for ion implantation of a workpiece. The method comprises generating an ion beam, scanning the ion beam across the workpiece in a first direction to produce scan lines, translating the workpiece in a second direction relative to the ion beam so that the scan lines are distributed over the workpiece, and controlling the spatial frequency of the scan lines on the workpiece in accordance with a desired dose map.

According to another aspect of the invention, a method for ion implantation of a workpiece is provided. The method comprises generating an ion beam, scanning the ion beam across the workpiece in a first direction to produce scan lines, translating the workpiece in a second direction relative to the ion beam so that the scan lines are distributed over the workpiece with a standard spatial frequency, acquiring a dose map of the workpiece, and initiating a dose correction implant and controlling the spatial frequency of the scan lines during the dose correction implant, if the acquired dose map is not within specification and a required dose correction is less than a minimum dose correction that can be obtained with the standard spatial frequency of the scan lines.

The step of controlling the spatial frequency of the scan lines may comprise (a) selecting a group of n scan lines having the standard spatial frequency, where n represents the number of scan lines in the group, (b) determining if the minimum dose correction divided by the number n is less than or equal to the required dose correction, (c) initiating a scan of the ion beam over the selected scan line group if the minimum dose correction divided by the number n is less than or equal to the required dose correction, and (d) incrementing the number n of scan lines in the scan line group and repeating steps (b)-(d) if the minimum dose correction divided by the number n is not less than or equal to the required dose correction and the number n of scan lines in the selected scan line group is less than a maximum value. When the number n of scan lines in the selected scan line group is equal to the maximum value and the minimum dose correction divided by the number n is not less than or equal to the required dose correction, or following a scan, the next group of n scan lines is selected and evaluated in the same manner. This process is repeated across the entire set of scan lines or a subset thereof, and then the entire process may be repeated until the dose map is within specification.

According to a further aspect of the invention, ion implantation apparatus is provided. The ion implantation apparatus comprises an ion beam generator for generating an ion beam, a scanner for scanning the ion beam across a workpiece in a first direction to produce scan lines, a mechanical translator for translating the workpiece in a second direction relative to the ion beam so that the scan lines are distributed over the workpiece with a standard spatial frequency, a dose measurement system for acquiring a dose map of the workpiece, and a controller for initiating a dose correction implant and for controlling the spatial frequency of the scan lines during the dose correction implant, if the acquired dose map is not within specification and a required dose correction is less than a minimum dose correction that can be obtained with the standard spatial frequency of the scan lines.

### BRIEF DESCRIPTION OF THE DRAWINGS

For a better understanding of the present invention, reference is made to the accompanying drawings, which are incorporated by reference and in which:

FIG. 1 is a top schematic view of an ion implanter suitable for implementing the present invention;

FIG. 2 is a side schematic view of the ion implanter of FIG. 1;

FIG. 3A is a graph of applied dose in percent as a function of scan line, for the case where the ion beam was interrupted near the middle of the wafer;

FIG. 3B is a graph of applied dose in percent as a function of scan line, for the case where a prior art dose control algorithm is utilized to correct the dose profile shown in FIG. 3A;

FIG. 3C is a graph of applied dose in percent as a function of scan line, for the case where a dose control algorithm in accordance with an embodiment of the invention is utilized to correct the dose profile shown in FIG. 3A;

FIG. 4 is a flow chart of a process for ion implantation including dose control in accordance with an embodiment of the invention; and

FIG. 5 is a flow chart of an embodiment of the variable spatial frequency dose correction algorithm shown in FIG. 4.

### DETAILED DESCRIPTION

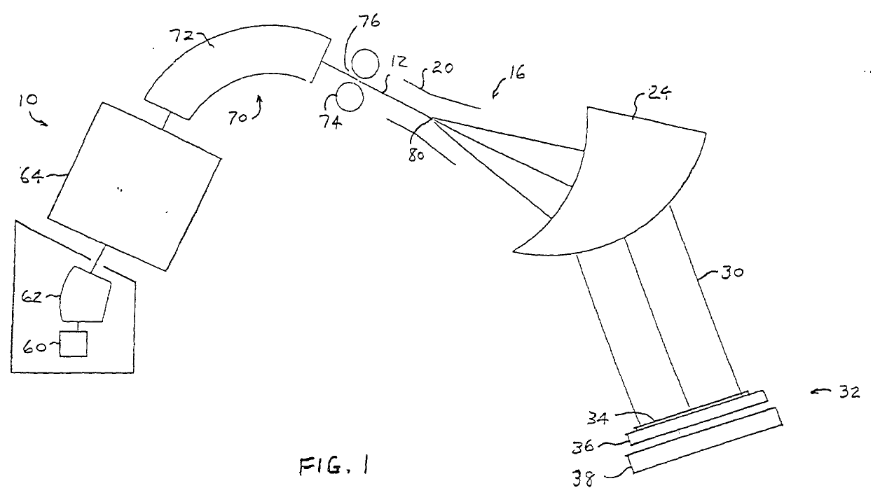

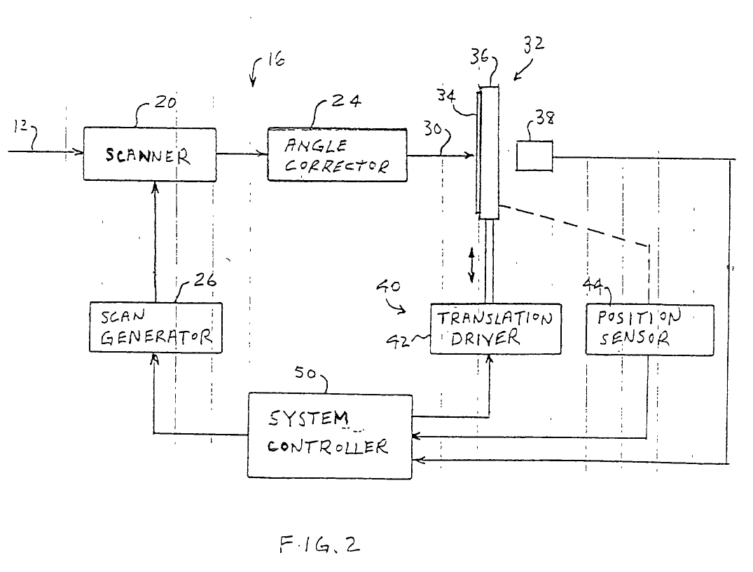

Simplified block diagrams of an embodiment of an ion implanter suitable for incorporating the present invention are shown in FIGS. 1 and 2. FIG. 1 is a top view, and FIG. 2 is a side view. Like elements in FIGS. 1 and 2 have the same reference numerals.

An ion beam generator 10 generates an ion beam of a desired species, accelerates ions in the ion beam to desired energies, performs mass/energy analysis of the ion beam to remove energy and mass contaminants and supplies an energetic ion beam 12 having a low level of energy and mass contaminants. A scanning system 16, which includes a scanner 20, an angle corrector 24 and a scan generator 26, deflects the ion beam to produce a scanned ion beam 30 having parallel or nearly parallel ion trajectories.

An end station 32 includes a platen 36 that supports a semiconductor wafer 34 or other workpiece in the path of scanned ion beam 30 such that ions of the desired species are implanted into the semiconductor wafer 34. End station 32 may include a Faraday cup 38 for monitoring the ion beam dose and dose uniformity.

As shown in FIG. 2, the ion implanter includes a mechanical translation system 40 for mechanically moving platen 36 and wafer 34 in a vertical direction. The mechanical translation system 40 includes a translation driver 42 mechanically coupled to platen 36 and a position sensor 44 for sensing the vertical position of platen 36. A system controller 50 receives signals from Faraday cup 38 and position sensor 44 and provides control signals to scan generator 26 and translation driver 42. By way of example, system controller 50 may be implemented as a programmed general purpose microprocessor with appropriate memory and other peripheral devices. System controller 50 preferably includes a dose control system.

The ion beam generator 10 may include an ion beam source 60, a source filter 62, an acceleration/deceleration column 64 and a mass analyzer 70. The source filter 62 is preferably positioned in close proximity to ion beam source 60. The acceleration/deceleration column 64 is positioned between source filter 62 and mass analyzer 70. The mass analyzer 70 includes a dipole analyzing magnet 72 and a mask 74 having a resolving aperture 76.

The scanner 20, which may be an electrostatic scanner, deflects ion beam 12 to produce a scanned ion beam having trajectories which diverge from a scan origin 80. The scanner 20 may comprise spaced-apart scan plates connected to scan generator 26. The scan generator 26 applies a scan voltage waveform, such as a triangular waveform, for scanning the ion beam in accordance with the electric field between the scan plates. The ion beam is typically scanned in a horizontal plane.

Angle corrector 24 is designed to deflect ions in the scanned ion beam to produce scanned ion beam 30 having parallel ion trajectories, thus focusing the scanned ion beam. In particular, angle corrector 24 may comprise magnetic polepieces which are spaced apart to define a gap and a magnet coil which is coupled to a power supply (not shown). The scanned ion beam passes through the gap between the polepieces and is deflected in accordance with the magnetic field in the gap. The magnetic field may be adjusted by varying the current through the magnet coil.

In operation, scanning system 16 scans ion beam 12 across wafer 34 in a horizontal direction, and mechanical translation system 40 translates platen 36 and wafer 34 vertically with respect to scanned ion beam 30. The scanning system 16 produces scan lines on the surface of wafer 34. A combination of electronic scanning of ion beam 12 and mechanical translation of wafer 34 causes the scan lines to be distributed over the surface of wafer 34. The ion beam current is measured by Faraday cup 38 when platen 36 is in a lowered position, and a signal representative of ion beam current is supplied to system controller 50. In another embodiment, the Faraday cup is located adjacent to wafer 34 and is scanned intermittently. The electronic scan speed can be varied as a function of horizontal beam position to achieve dose uniformity.

A typical implant of a semiconductor wafer involves multiple complete passes over the wafer to achieve a desired dose for a given beam current and scanning protocol. For example, ten complete passes over the wafer may be required to achieve a specified dose, and a greater number of passes would be required to achieve a higher dose level. A “pass” refers to the combined electronic scanning and mechanical translation which distributes the ion beam over the wafer. In one example, the ion beam is scanned electronically and is translated mechanically to produce a standard spatial frequency of about 40 scan lines per inch. Thus, a large wafer may require several hundred scan lines for a complete pass. Typically, the ion beam has a height in the mechanical translation direction of about one centimeter or greater. Thus, the scanning protocol having a spatial frequency of 40 scan lines per inch results in overlapping scan lines and promotes dose uniformity. During the implant, a dose map is generated from measurements of ion beam current. The dose map is representative of ion dose over the surface area of the wafer and thus provides a dose profile of the wafer, including both dose and dose uniformity. As the implant progresses and each pass over the wafer is completed, the dose map is updated, and the dose levels are compared with desired dose levels at multiple locations on the wafer. When the desired dose level is reached, the implant is terminated.

Deviations from the desired dose map may result from a number of sources, including ion beam glitches and ion beam drift. In addition, ion implanters are typically interlocked to turn off the ion beam if the pressure in the implant chamber goes outside prescribed limits as a result, for example, of photoresist outgassing. When the pressure goes outside the prescribed limits, the ion beam is turned off until the desired pressure is restored. Thus, a given implant is subject to beam current variations including beam turn off. Such beam current variations adversely affect the dose map.

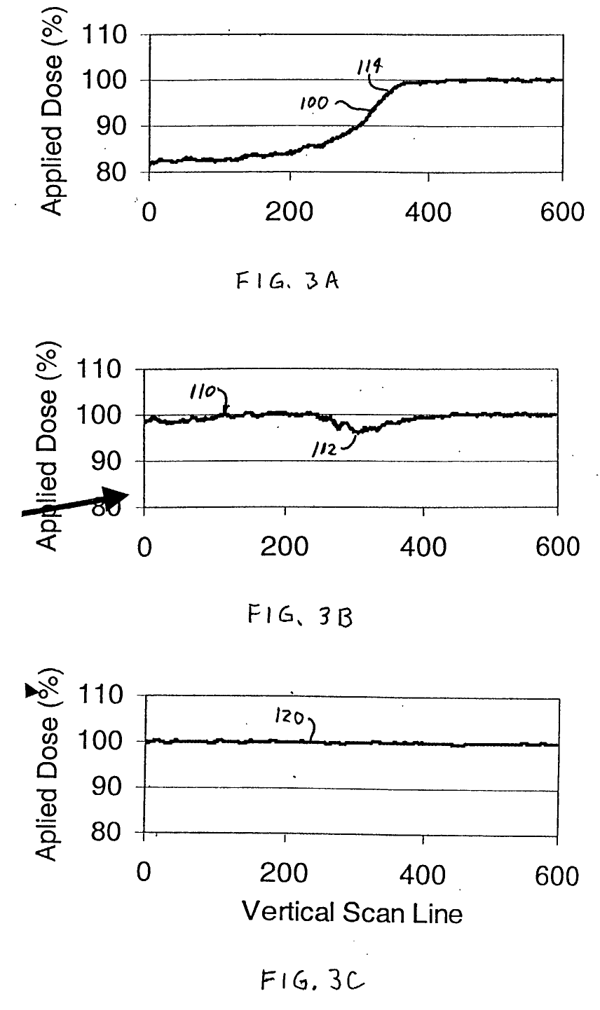

Referring to FIG. 3A, a dose map is shown wherein applied dose in percent of desired dose is plotted as a function of scan line number. In the example of FIG. 3A, the implant has 600 scan lines, with scan line 0 representing the bottom of the wafer and scan line 600 representing the top of the wafer. A dose curve 100 illustrates an example where the ion beam was interrupted from scan lines 0 to 200 and then was gradually restored between scan lines 200 and 400. It can be seen that the dose is significantly below the desired dose in the lower portion of the wafer.

The response to the beam current interruption of FIG. 3A according to prior art dose control algorithms is shown in FIG. 3B. The dose control system determines that the dose is below specification in the lower portion of the wafer by comparing the actual dose represented by the dose map with the desired dose. A dose correction implant is performed to increase the dose in the lower portion of the wafer to 100 percent of the specified dose. This is done by scanning the lower portion of the wafer with scan lines having the standard spatial frequency until the actual dose is as close as possible to the specified dose.

As shown in FIG. 3B, a dose curve 110 exhibits a region 112 near the center of the wafer where the actual dose is below the desired dose. The reason for the region 112 of reduced dose is as follows. The position of region 112 corresponds to region 114 in FIG. 3A where the dose was slightly below the desired dose. Thus, in region 114 a relatively small dose correction is required. However, prior art dose control systems were characterized by a minimum dose correction that could be applied. The minimum correction resulted from the fact that the ion beam current and the scanning protocol were fixed. The scanning protocol, which in the above example had a standard spatial frequency of 40 scan lines per inch, was utilized to ensure dose uniformity over the wafer surface. The dose correction can be decreased by increasing the electronic scan speed, thereby reducing the number of ions implanted per unit area. However, the electronic scan speed has a maximum value that is determined by the characteristics of scan generator 26 (FIG. 2). As a result, the prior art dose control system was limited by a minimum dose correction that could be obtained with the standard spatial frequency of the scan lines. The minimum dose correction varied with implant recipe but could be as high as 5 to 10%. If the wafer is scanned using the minimum dose correction in a region, such as region 114, where the minimum dose correction is greater than the required dose correction, the actual dose will exceed the desired dose. The dose control system is typically programmed to avoid exceeding the desired dose. Thus, in cases where the minimum dose correction is greater than the required dose correction, the minimum dose correction is not applied, and region 112 is underdosed. Such underdosing may be unacceptable to semiconductor manufacturers.

In accordance with a feature of the invention, the spatial frequency of the scan lines is controlled to achieve the desired dose profile. In particular, the spatial frequency of scan lines is reduced in regions of the wafer that require a dose correction that is less than the minimum dose correction that can be obtained with the standard spatial frequency of scan lines. A group of scan lines having the standard spatial frequency may be scanned with a single scan line. Thus, for example, three scan lines having the standard spatial frequency, each requiring one third of the minimum dose correction, are corrected by a single scan across the center of the three scan lines. This process may be repeated for groups of scan lines across the entire wafer surface or a selected part of the wafer surface. The technique relies upon the fact that the ion beam height in the mechanical translation direction is greater than the scan line spacing that corresponds to the standard spatial frequency of the scan lines. A group of scan lines is defined as two or more contiguous scan lines having the standard spatial frequency of the scanning protocol. The number of scan lines in the group is determined according to the magnitude of the required dose correction. The maximum number of scan lines in a group depends on the beam height in the mechanical translation direction. The technique produces a desired dose map, as illustrated for example by dose curve 120 in FIG. 3C. When the invention is utilized, the minimum dose correction that can be obtained with the standard spatial frequency of scan lines no longer places a lower limit on dose correction.

The number n of scan lines having the standard spatial frequency in a group of scan lines may be selected by dividing the minimum dose correction obtainable with the standard spatial frequency of scan lines by the required dose correction. Thus, for example, where the minimum dose correction is 10% and the required dose correction is 2%, the number n of scan lines in a group is 10/2=5. If the number n that results from the minimum dose correction divided by the required dose correction is not an integer value, the value of n is rounded to the next higher integer. In an equivalent process described below, a group of scan lines having a small number n of scan lines is selected, and the number n is incremented until the minimum dose correction divided by the number n is less than or equal to the required dose correction. The number n of scan lines in a group may vary over the surface of the wafer as the required dose correction varies according to the dose map. The maximum number n_max of scan lines in a group may be determined by dividing the ion beam height in the mechanical scan direction by the standard spacing between scan lines. This ensures that a single scan of the scan line group covers all the scan lines in the group.

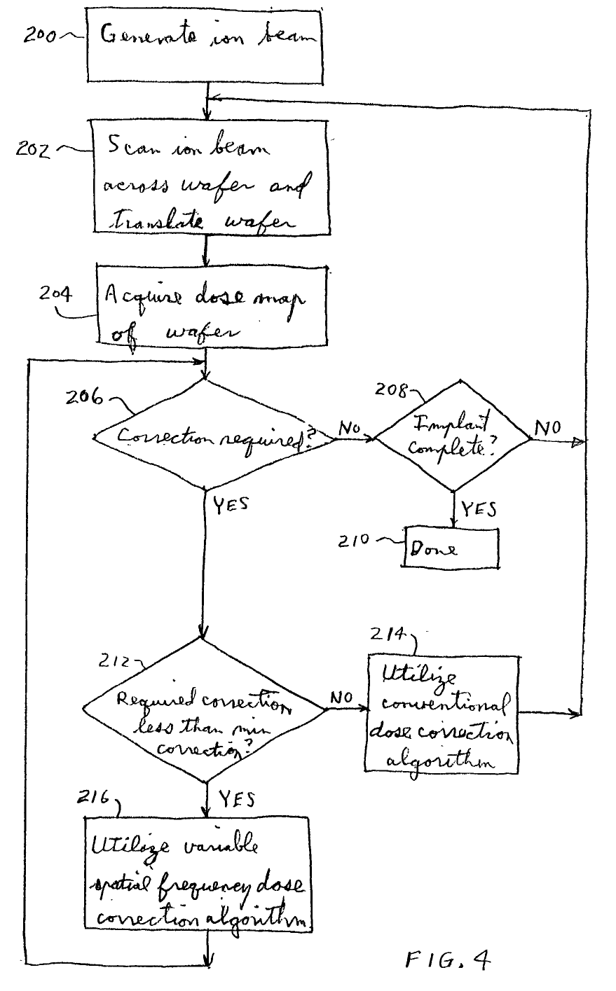

A flow chart of a process for ion implantation including dose control in accordance with an embodiment of the invention is shown in FIG. 4. The process is implemented by software in system controller 50 (FIG. 2) and is used to control scan generator 26 and translation driver 42.

Referring to FIG. 4, an ion beam is generated in step 200. The ion beam may be generated by ion beam generator 10 shown in FIG. 1 and described above. In step 202, the ion beam is scanned across a semiconductor wafer or other workpiece in a first direction by the scanning system 16, and the wafer is translated in second direction relative to the scanned ion beam by mechanical translation system 40. An implant is performed in accordance with a specified implant recipe to provide a specified dose of dopant ions in the wafer. Required dose accuracy and dose uniformity are typically better than 1%.

In step 204, a dose map of the wafer is acquired. The dose map may be generated by the system controller 50 in response to beam current measurements by Faraday cup 38 during the implant. The dose map represents the dose profile, including dose and dose uniformity, of the semiconductor wafer. The dose map may be acquired cumulatively as the implant progresses. An implant may require one or more complete passes over the wafer surface.

In step 206, a determination is made as to whether a dose correction is required. The acquired dose map is evaluated, typically by comparing the specified dose from the recipe with the measured dose at multiple locations in the dose map. The determination as to whether a dose correction is required may be based on whether the dose map meets a predetermined criteria with respect to dose and dose uniformity. In one embodiment, a dose correction is required if: (1) the uniformity of the acquired dose map is less than a prescribed value (this condition may occur at any time during the implant), or (2) the difference between the desired dose and the measured dose is less than the minimum dose correction, whether or not the acquired dose map is uniform (this condition occurs near the end of the implant). If a dose correction is not required, the implant continues until the desired dose is implanted.

If a determination is made in step 206 that a dose correction is not required, a determination is made in step 208 as to whether the implant is complete. If the implant is complete with respect to dose and dose uniformity, the process is done in step 210. If a determination is made in step 208 that the implant is not complete, the process returns to step 202 for additional scanning of the ion beam across the workpiece and translation of the wafer. A typical implant may require multiple complete scans, or passes, over the semiconductor wafer.

If a determination is made in step 206 that a dose correction is required, the process proceeds to step 212. In step 212, a determination is made as to whether the required dose correction is less than the minimum dose correction that can be obtained with the standard spatial frequency of scan lines. The minimum dose correction, typically a known quantity, is a function of the ion beam current, the ion beam cross-sectional area, the maximum scan speed and the standard spatial frequency of scan lines. If a determination is made in step 212 that the required dose correction is not less than the minimum dose correction, a conventional dose correction algorithm is utilized in step 214. The conventional dose correction algorithm may include adjusting the scan waveform to obtain a desired dose distribution. More specifically, the scan speed may be decreased in areas where increased dose is required, and may be increased in areas where decreased dose is required. The process then returns to step 202 to perform a pass over the semiconductor wafer with the corrected waveform.

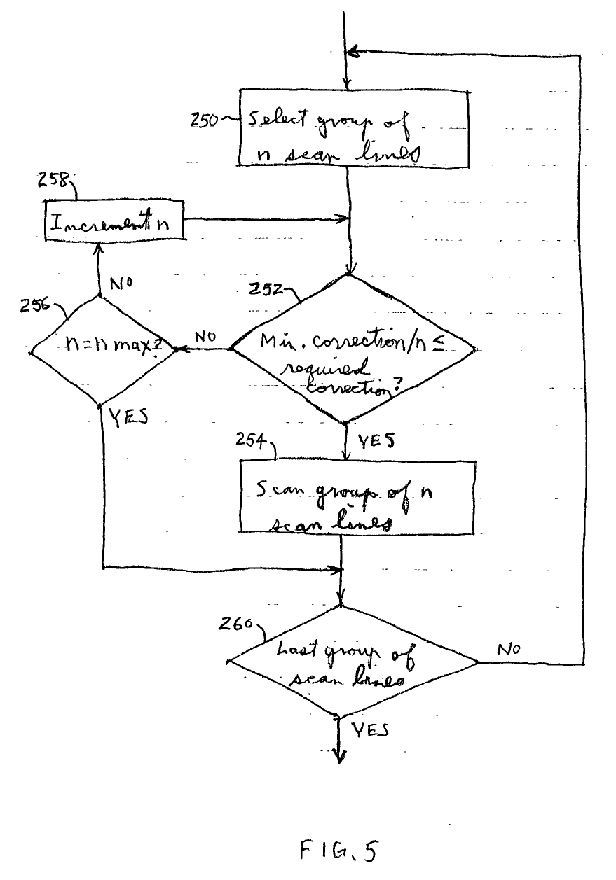

If a determination is made in step 212 that the required dose correction is less than the minimum dose correction, the process proceeds to step 216. In step 216, a variable spatial frequency dose correction algorithm is utilized. The variable spatial frequency dose correction algorithm is typically utilized near the end of an implant. For example, assume that the minimum dose correction that can be obtained with the standard spatial frequency of scan lines is 10% and that the current dose implanted into the wafer, as determined from the acquired dose map, is 95% of the desired dose. In this case, the conventional dose correction algorithm utilizing the minimum dose correction would produce a 5% overdose of the wafer. Accordingly, the variable spatial frequency dose correction algorithm is utilized. An embodiment of the variable spatial frequency dose correction algorithm is described below in connection with FIG. 5. Following step 216, the process may return to step 206 to determine if additional dose correction is required. Alternatively, the implant process may be considered as complete following step 216.

A flow chart of an embodiment of the variable spatial frequency dose correction algorithm is shown in FIG. 5. A group of n scan lines having the standard spatial frequency is selected in step 250, where n represents the number of scan lines in the group. The initial selected group of scan lines is typically at or near one edge of a region requiring dose correction. The region requiring dose correction may include a part of the wafer or the entire wafer. In the example of FIG. 3B, region 112 requiring correction is located near the center of the wafer. The initial scan line group selected in step 250 may include two adjacent scan lines.

In step 252, a determination is made as to whether the minimum dose correction that can be obtained with a standard spatial frequency of scan lines divided by the number n of scan lines in the scan line group is less than or equal to the required dose correction. Thus, for example, if the group includes two scan lines (n=2), the minimum dose correction is 10% and the required dose correction is 2%, the minimum dose correction divided by n is not less than or equal to the required dose correction. If the above example is changed such that the required dose correction is 5%, then the minimum dose correction divided by n is less than or equal to the required dose correction. When a determination is made in step 252 that the minimum dose correction divided by the number n is less than or equal to the required dose correction, the group of n scan lines is scanned in step 254, preferably using a single scan line at or near the center of the selected group of n scan lines.

If a determination is made in step 252 that the minimum dose correction divided by the number n is not less than or equal to the required dose correction, a determination is made in step 256 as to whether the number n of scan lines in the group is equal to a maximum value n_max. The maximum number n_max of scan lines in the group may be based on the height of the ion beam in the mechanical translation direction. Typical beam heights are one centimeter or greater. Thus, the maximum number n_max of scan lines may be 15 or greater for a standard spatial frequency of 40 scan lines per inch. If the number of scan lines is equal to the maximum value n_max, no dose correction is made and the process proceeds to step 260. A dose correction is not made in this case in order to avoid exceeding the desired dose.

If the number of scan lines is determined in step 256 to be less than the maximum number n_max, the number n of scan lines in the group is incremented in step 258, typically by one scan line, and the process returns to step 252. In step 252, a determination is made as to whether the minimum dose correction divided by the new value of the number n is less than or equal to the required dose correction for the newly-selected group of scan lines. The number n of scan lines in the group is incremented until the minimum dose correction divided by the new value of the number n is less than or equal to the required dose correction, or until the maximum number n_max of scan lines in the group is reached. If the minimum dose correction divided by the number n of scan lines n the group is less than or equal to the required dose correction, the group of n scan lines is scanned in step 254, preferably by a single scan at or near the center of the scan line group. The scan at or near the center of the scan line group can be accomplished by delaying the start of the scan line relative to mechanical translation of the wafer to position the scan line at or near the center of the scan line group.

In the above example where the required dose correction is 2% and the minimum dose correction is 10%, a group of 5 contiguous scan lines is utilized by the variable spatial frequency dose correction algorithm. In this case, the dose correction is made by a single scan at or near the middle of the five scan line group, with the ion beam being spread over all scan lines in the group.

In step 260, a determination is made as to whether the current group of scan lines is the last group that requires dose correction. If the current group is not the last group, the process returns to step 250, and a new group of n scan lines having the standard spatial frequency is selected. The new group may be adjacent to the previous group, so as to proceed in an orderly manner across the region that requires dose correction. Alternatively, the new group may be in another region of the wafer that requires dose correction. The process described above is repeated for each selected group of scan lines until the region that requires dose correction has been completed. The number of scan lines in each group is incremented until the minimum dose correction divided by the number n of scan lines in the group is less than or equal to the required dose correction. As the wafer is scanned utilizing the variable spatial frequency dose correction algorithm, updates to the dose map are acquired by Faraday cup 38 (FIG. 2).

If the current group of scan lines is determined in step 260 to be the last group that requires correction, the process may return to step 206 (FIG. 4). In step 206, a determination is made as to whether further dose correction is required. Thus, the process verifies that the variable spatial frequency dose correction algorithm has achieved the desired dose map. Alternatively, the implant maybe considered as complete following step 260 without further verification of the dose map.

The disclosed technique has the effect of reducing the spatial frequency of scan lines relative to the standard spatial frequency and decreasing the dose correction that may be applied to the wafer as compared to the minimum dose correction that may be obtained with the standard spatial frequency of scan lines. By varying the number of scan lines in each scan line group, the spatial frequency of scan lines and the dose correction are adjusted to provide the required dose correction. Thus, a relatively low spatial frequency of scan lines is utilized to obtain a small dose correction. Conversely, a relatively high spatial frequency of scan lines is used to obtain a larger dose correction.

The variable spatial frequency dose correction algorithm may be utilized near the end of an implant to perform dose corrections. The dose corrections may be performed in selected regions of the wafer or over the entire wafer surface. In another embodiment, control of spatial frequency of scan lines may be used to perform low dose implants. This approach may be utilized in cases where a single pass over the wafer using the standard scanning protocol would result in a dose that exceeds the specified dose. Thus, the control of spatial frequency of scan lines may provide a technique for performing low dose implants.

In the example of FIG. 5, the maximum number n_max of scan lines in a group was fixed. In another embodiment, the maximum number of scan lines in a scan line group can be adjustable or programmable in accordance with the ion beam height in the mechanical translation direction. Where the beam height is relatively large, the maximum number n_max of scan lines in a scan line group can be increased, thereby increasing the range of possible dose corrections.

While there have been shown and described what are at present considered the preferred embodiments of the present invention, it will be obvious to those skilled in the art that various changes and modifications may be made therein without departing from the scope of the invention as defined by the appended claims.

What is claimed:

1. A method for ion implantation of a workpiece, comprising:
generating an ion beam;
scanning the ion beam across a workpiece in a first direction to produce scan lines;
translating the workpiece in a second direction relative to the ion beam so that the scan lines are distributed over the workpiece; and
controlling a spatial frequency of the scan lines on the workpiece in accordance with a desired dose map.

2. A method as defined in claim 1, wherein the step of controlling the spatial frequency of the scan lines comprises decreasing the spatial frequency of the scan lines to achieve a required dose correction which is less than a minimum dose correction that can be obtained with a standard spatial frequency of the scan lines.

3. A method as defined in claim 1, wherein the step of controlling the spatial frequency of the scan lines comprises scanning a group of n scan lines having a standard spatial frequency with a single scan, where the number n scan lines in the group is equal to or greater than a minimum dose correction that can be obtained with the standard spatial frequency of scan lines divided by a required dose correction.

4. A method as defined in claim 3, wherein the group of scan lines has a width that is less or equal to the cross-sectional dimension of the ion beam in the direction of workpiece translation.

5. A method as defined in claim 1, wherein the step of controlling the spatial frequency of the scan lines comprises acquiring a dose map of the workpiece, evaluating the dose map to determine a required dose correction and varying the spatial frequency of the scan lines on the workpiece to achieve the required dose correction.

6. A method as defined in claim 1, wherein the step of controlling the spatial frequency of the scan lines is utilized near the end of an implant.

7. A method as defined in claim 1, wherein the step of controlling the spatial frequency of the scan lines is utilized during some or all of the implant of the workpiece.

8. A method for ion implantation of a workpiece, comprising:
generating an ion beam;
scanning the ion beam across a workpiece in a first direction to produce scan lines;
translating the workpiece in a second direction relative to the ion beam so that the scan lines are distributed over the workpiece with a standard spatial frequency;
acquiring a dose map of the workpiece; and
initiating a dose correction implant and controlling the spatial frequency of the scan lines during the dose correction implant, if the acquired dose map is not within specification and a required dose correction is less than a minimum dose correction that can be obtained with the standard spatial frequency of the scan lines.

9. A method as defined in claim 8, wherein the step of controlling the spatial frequency of the scan lines comprises:
(a) selecting a group of n scan lines having the standard spatial frequency, where n represents the number of scan lines in the group;
(b) determining if the minimum dose correction divided by the number n is less than or equal to the required dose correction;
(c) if the minimum dose correction divided by the number n is less than or equal to the required dose correction, scanning the ion beam over the selected group of scan lines; and
(d) if the minimum dose correction divided by the number n is not less than or equal to the required dose correction and the number n of scan lines in the scan line group is less than a maximum value, incrementing the number n of scan lines in the scan line group and repeating steps (b)-(d).

10. A method as defined in claim 9, wherein the number n of scan lines in the scan line group is at least two.

11. A method as defined in claim 9, wherein the maximum value of the number n of scan lines in the scan line group is based on the height of the ion beam in the second direction.

12. A method as defined in claim 9, further comprising the step of adjusting the maximum value of the number n of scan lines in the scan line group in accordance with the height of the ion beam in the second direction.

13. A method as defined in claim 8, wherein the step of controlling the spatial frequency of the scan lines comprises reducing the spatial frequency of the scan lines to less than the standard spatial frequency.

14. A method as defined in claim 8, wherein the step of controlling the spatial frequency of the scan lines comprises controlling the start of the scan lines relative to the translation of the workpiece in the second direction.

15. A method as defined in claim 8, wherein the step of controlling the spatial frequency of the scan lines is performed near completion of the implant of the workpiece.

16. Ion implantation apparatus comprising:
an ion beam generator for generating an ion beam;
a scanner for scanning the ion beam across a workpiece in a first direction to produce scan lines;
a mechanical translator for translating the workpiece in a second direction relative to the ion beam so that the scan lines are distributed over the workpiece with a standard spatial frequency;
a dose measurement system for acquiring a dose map of the workpiece; and
a controller for initiating a dose correction implant and controlling the spatial frequency of the scan lines during the dose correction implant, if the acquired dose map is not within specification and the required dose correction is less than a minimum dose correction that can be obtained with the standard spatial frequency of the scan lines.

17. Ion implantation apparatus as defined in claim 16, wherein said controller comprises:
means for selecting a group of n scan lines having the standard spatial frequency, where n represents the number of scan lines in the group;
means for determining if the minimum dose correction divided by the number n is less than or equal to the required dose correction;
means for scanning the ion beam over the selected scan line group if the minimum dose correction divided by the number n is less than or equal to the required dose correction; and
means for incrementing the number of scan lines in the scan line group and for repeating the operations of determining, scanning and incrementing if the minimum dose correction divided by the number n is not less than or equal to the required dose correction and the number n of scan lines in the selected scan line group is less than a maximum value.

18. Ion implantation apparatus as defined in claim 17, wherein said means for selecting a scan line group comprises means for selecting a group of at least two scan lines.

19. Ion implantation apparatus as defined in claim 17, wherein the maximum value of the number n of scan lines in the selected scan line group is based on the height of the ion beam in the second direction.

20. Ion implantation apparatus as defined in claim 19, wherein said controller further comprises means for adjusting the maximum value of the number n of scan lines in the selected scan line group in accordance with the height of the ion beam in the second direction.
